(19) United States
(12) Patent Application Publication
(10) Pub. No.: US 2011/0253194 A1
(43) Pub. Date: Oct. 20, 2011

(54) PHOTOELECTRIC CONVERSION

(76) Inventors: Chien-Feng LIN, Hsinchu City (TW); Cheng-Yu Huang, Taoyuan County (TW); Te-Kai Ku, Hsinchu county (TW); Chuan-Yi Lin, Hsinchu City (TW)

(21) Appl. No.: 12/760,000

(22) Filed: Apr. 14, 2010

(51) Int. Cl. H01L 31/052

(52) U.S. Cl. 136/246

(57) ABSTRACT

A photoelectric conversion is capable of converting the light energy into electrical power, comprising a tempered glass layer, a lens module, a substrate and a heat sink unit, wherein the lens module is formed from a plurality of lens units, which locate at one side of the tempered glass layer. A gap is formed via a plurality of protruding poles located between the lens units and the tempered glass layer. The gap is filled with transparent rubbers. A plurality of receiving units is located one side of the substrate for dissipating heat energy from the receiving units. The light energy is converted through the receiving units into the electrical energy by focusing the light to the receiving units via the tempered glass layer and the lens module.

### FIELD OF THE INVENTION

The present invention relates to a photoelectric conversion, and more particularly to a photoelectric conversion modules.

### BACKGROUND OF THE INVENTION

The conventional photoelectric conversions are made from lens and photoelectric converting units, for example, the lens are utilized to focus the light onto the photoelectric converting units, wherein the photoelectric converting units are mostly made from semiconductor materials. During the manufacturing process, the photoelectric converting units are formed on the substrate, and the photoelectric converting units then undergo through the photoelectrical conversion. Since the photoelectric converting units are used for outdoor purpose, they are easily subjected to the weathering conditions, such as the sun exposedness or raining, can have a drastically effect on the surfaces of the lens units. Further since the materials of the lens units have low degree of hardness, they are easily damaged through the outdoor weathering conditions.

### SUMMARY OF THE INVENTION

These features and advantages of the present invention will become more fully apparent from the following description and appended claims, or may be learned by the practice of the invention as set forth thereinafter.

The photoelectric conversion of the present invention converts a light energy from a light source into an electrical power via the lens module and the receiving units.

The photoelectric conversion of the present invention arranges the lens units with predetermined distances from each other around the lens module via the protruding poles so the transparent rubber filled in the gaps have a predetermined height.

The photoelectric conversion of the present invention, capable of converting a light energy from a light source into an electrical power, comprising: a tempered glass layer, a lens module, a substrate and a heat sink unit. The lens module is formed from a plurality of lens units, wherein the lens units positioned at one side of the tempered glass layer, and a gap is formed via a plurality of protruding poles located between the tempered glass layer and the lens units, and a transparent rubber is filled in the gap. A plurality of receiving units is located at the substrate, wherein the receiving units are located correspondingly to the positions of the lens units. One side of the substrate comprises the heat sink unit for dissipating heat received from the receiving units. The light energy is converted through the receiving units into the electrical energy by focusing the light to the receiving units via the tempered glass layer and the lens module.

The photoelectric conversion of the present invention provides a property of high numbers of modules so that when one part of the lens units is damaged, it can be replaced easily. Further, the transparent rubber is used to adhere closely to the tempered glass layer and the lens units through the protruding poles such that the whole photoelectric conversion consists of high durable characteristic. The dissipating heat units located at one side of the substrates of the receiving units are designed to resolve the heat energy generated problem during the photoelectrical conversion so that the life span of the photoelectric conversion of the present invention is drastically increased.

### BRIEF DESCRIPTION OF THE DRAWINGS

In order for the advantages of the invention to be readily understood, a more particular description of the invention briefly described above will be rendered by reference to specific embodiments that are illustrated in the appended drawings. Understanding that theses drawings depict only typical embodiments of the invention and are not therefore to be considered to be limiting of its scope, the invention will be described and explained with additional specificity and detail through the use of the accompanying drawings, in which:

FIG. 1 is a schematic view of a photoelectric conversion in accordance with a preferred embodiment of the present invention;

FIG. 2 is a detailed schematic view of the lens module of the photoelectric conversion in accordance with the preferred embodiment of the present invention of FIG. 1;

FIG. 3 is a detailed schematic view of the lens module of the photoelectric conversion in accordance with the preferred embodiment of the present invention of FIG. 2;

FIG. 4 is a detailed schematic view of the light conversion through the photoelectric conversion in accordance with the preferred embodiment of the present invention of FIG. 1; and

FIG. 5 is a detailed schematic view of the photoelectric conversion in accordance with the preferred embodiment of the present invention of FIG. 1.

### DETAILED DESCRIPTION OF THE PREFERRED EMBODIMENTS

For the purpose of promoting an understanding of the principles of the invention, reference will now be made to the exemplary embodiments illustrated in the drawings, and specific language will be used to describe the same. It will nevertheless be understood that no limitation of the scope of the invention is thereby intended. Any alterations and further modifications of the inventive features illustrated herein, and any additional applications of the principles of the invention as illustrated herein, which would occur to one skilled in the relevant art and having possession of this disclosure, are to be considered within the scope of the invention.

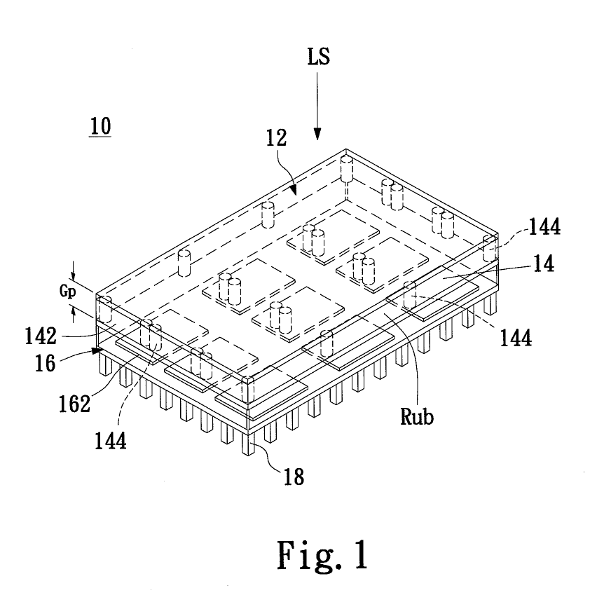

Refer to FIG. 1, a schematic view of a photoelectric conversion in accordance with a preferred embodiment of the present invention. The photoelectric conversion 10 is utilized a light source LS to convert into the electrical power, the LS can be from the sunlight. The photoelectric conversion 10 comprises a tempered glass layer 12, a lens module 14, a substrate 16 and a heat sink unit 18, wherein the tempered glass layer 12 is used to strengthen the surface hardness of the photoelectric conversion 10 and protect the lens module 14. The lens module 14 comprises a plurality of lens units 142 and those lens units 142 locate at one side of the tempered glass layer 12. A gap Gp is formed from a plurality of protruding poles 144 in between the lens units 142 and the tempered glass layer 12. The gap Gp is filled with transparent rubbers Rub. It is worthy of notice that the height of protruding poles 144 is pre-determined and fixed so that the final thickness of the transparent rubbers Rub filled up the gap Gp will be the same as the height of the protruding poles 144 in such that the lens module 14 is adhered to the tempered glass layer 12 securely.

The transparent rubbers Rub has a high coefficient of transparency and is popularly utilized as it allows the light to penetrate effortlessly, as a result, the lost of the light energy of the light source LS is minimum. Further, the transparent rubbers Rub has a very low coefficient of thermal expansion, therefore, when the light penetrates through the transparent rubbers Rub, the thermal expansion of the transparent rubbers Rub is minimized. According to the best mode of the embodiments, the thickness of the transparent rubbers Rub is preferably smaller than 1 mm.

The substrate 16 comprises a plurality of receiving units 162, wherein the receiving units 162 is located correspondingly to the lens units 142 so that the receiving units 162 convert the light energy received from the corresponding lens units 142 into the electrical energy. The receiving units 162 of the substrate 16 are located respectively to the focal points of the lens units 142 or the focal points adjacent to the lens units 142. The locations of the receiving units 162 at the focal points of the lens units 142 allow the receiving unites 162 to receive and cumulate all the light energy via the lens units 142 and then convert those light energy into the electrical energy to increase the photoelectric conversion efficiency. The heat sink unit 18 is positioned at one side of the substrate 16, and is used to dissipate the heat generated at the receiving units 162 during the conversion of light energy received through the lens units 142.

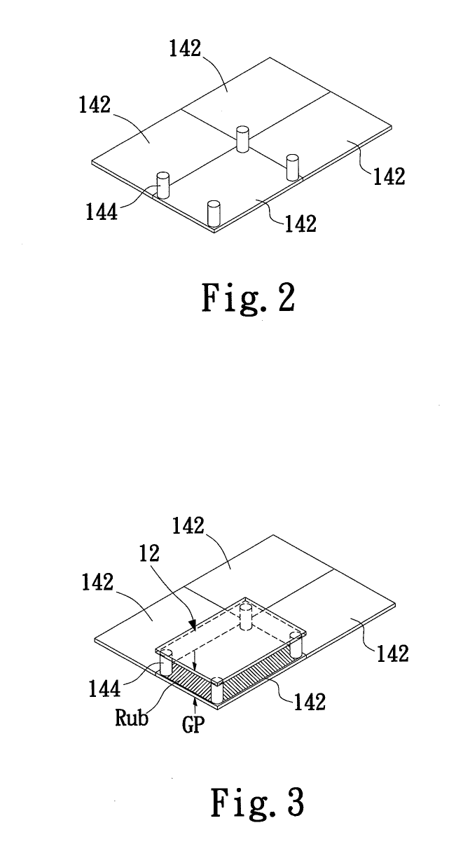

Refer to FIG. 2, a schematic view of the photoelectric conversion in accordance with the preferred embodiment of the present invention. The lens module 14 is formed from the integration of the lens units 142, the plurality of protruding poles 144 are arranged with predetermined distances from each other around the lens module 14 as shown in FIG. 2 so that the lens units 142 have equal gaps away each other. The lens units 142 comprise the characteristic of focusing the light. The light coming through one side of the lens units 142 is projected to one region of the lens units 142 via the light focusing feature of the lens units 142. As above-mentioned, the corresponding receiving units 162 receive the light energy focused through the lens units 142 and convert the light energy into the required electrical energy. The design and arrangement of the receiving units 162 and the lens units 142 of the photoelectric conversion 10 allow the light source to be focused and projected through the lens units 142 effectively.

One side of the protruding poles 144 is integrated with the tempered glass layer 12 in order to protect the lens units 142. Refer to FIG. 3, the lens units 142 of the present invention are protected from any damage resulting from the inadequate hardness of the lens units 142 so that the conversion efficiency of the photo-electricity will not be affected by the damage on the lens units 142. The external conditions such as the weathering conditions, sun exposedness or raining, can have a drastically effect on the surfaces of the lens units 142. Once the surfaces of the lens units 142 are withered or damaged, the efficiency of the photo-electricity conversion will be severally reduced. The gap Gp is formed via the protruding poles 144 located in between the tempered glass layer 12 and lens units 142. Transparent rubber Rub consisting of high coefficient of transparency and a low thermal expansion coefficient is filled in the gap Gp. The design of the transparent rubber Rub of the gap Gp is to reduce the light diffraction interference in the light transmission from the tempered glass layer 12 to the lens units 142. The high coefficient transparent and the low thermal expansion coefficient of the transparent rubber Rub is used to adhere closely to the tempered glass layer 12 and the lens units 142 in such that the thickness of the transparent rubber Rub is less than 1 mm.

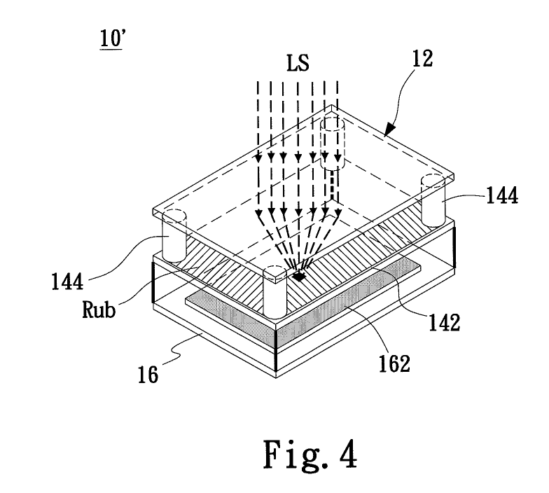

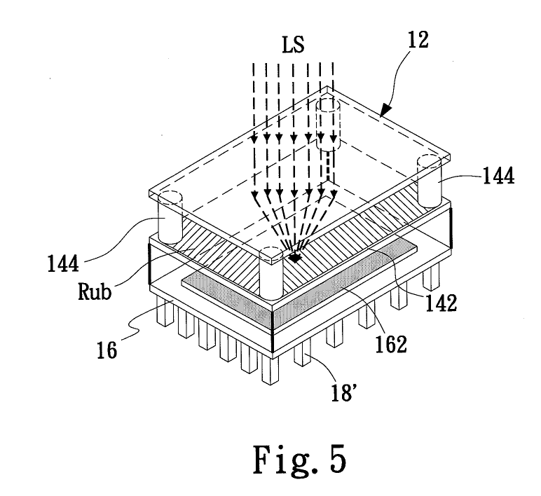

Refer to FIG. 4, a schematic view of the light conversion through the photoelectric conversion in accordance with the preferred embodiment of the present invention. FIGS. 1 and 4 show that the photoelectric conversion 10 is formed from assembling a plurality of the photoelectric conversions 10′ for the assembly of the module. When one of the photoelectric conversions 10′ is broken, the damaged photoelectric conversion 10′ can be replaced easily in the photoelectric conversion 10 without changing the whole unit of the photoelectric conversion 10. When the receiving units 162 of the photoelectric conversions 10′ precede the photoelectrical process, heat energy will be generated to affect the efficiency of photoelectrical conversion and the life span of inner devices of the photoelectric conversion 10. A heat sink unit 18′ is located at one side of the substrate of the receiving units 162 as shown in FIG. 5. The heat sink unit 18 is formed from a plurality of pole-shaped heat dissipaters, wherein the shape of the heat dissipaters is not limited to the pole shape, other shapes can be employed in the present invention, such as circular shape, square-shaped or other shapes of heat dissipaters.

Compare to the conventional technologies, the photoelectric conversion of the present invention provides a property of high numbers of modules so that when one part of the lens units is damaged, it can be replaced easily. Further, the transparent rubber is used to adhere closely to the tempered glass layer and the lens units through the protruding poles such that the whole photoelectric conversion consists of high durable characteristic. The dissipating heat units located at one side of the substrates of the receiving units are designed to resolve the heat energy generated problem during the photoelectrical conversion so that the life span of the photoelectric conversion of the present invention is drastically increased.

Reference throughout this specification to “one embodiment,” “an embodiment,” or similar language means that a particular feature, structure, or characteristic described in connection with the embodiment is included in at least one embodiment of the present invention. Thus, appearances of the phrases “one embodiment,” “an embodiment,” and similar language throughout this specification may, but do not necessarily, all refer to the same embodiment, different embodiments, or component parts of the same or different illustrated invention. Additionally, reference to the wording “an embodiment,” or the like, for two or more features, elements, etc. does not mean that the features are related, dissimilar, the same, etc. The use of the term “an embodiment,” or similar wording, is merely a convenient phrase to indicate optional features; which may or may not be part of the invention as claimed.

Each statement of an embodiment is to be considered independent of any other statement of an embodiment despite any use of similar or identical language characterizing each embodiment. Therefore, where one embodiment is identified as “another embodiment,” the identified embodiment is independent of any other embodiments characterized by the language “another embodiment.” The independent embodiments are considered to be able to be combined in whole or in part one with another as the claims and/or art may direct, either directly or indirectly, implicitly or explicitly.

Finally, the fact that the wording “an embodiment,” or the like, does not appear at the beginning of every sentence in the specification, such as is the practice of some practitioners, is merely a convenience for the reader's clarity. However, it is the intention of this application to incorporate by reference the phrasing “an embodiment,” and the like, at the beginning of every sentence herein where logically possible and appropriate.

Thus, while the present invention has been fully described above with particularity and detail in connection with what is presently deemed to be the most practical and preferred embodiment of the invention, it will be apparent to those of ordinary skill in the art that numerous modifications, including, but not limited to, variations in size, materials, shape, form, function and manner of operation, assembly and use may be made, without departing from the principles and concepts of the invention as set forth in the claims.

What is claimed is:

1. A photoelectric conversion, capable of converting a light energy from a light source into an electrical power, comprising:
a tempered glass layer,
a lens module, having a plurality of lens units, wherein the lens units positioned at one side of the tempered glass layer, and a gap is formed via a plurality of protruding poles located between the tempered glass layer and the lens units, and a transparent rubber is filled in the gap;
a substrate, having a plurality of receiving units, wherein the receiving units are located correspondingly to the positions of the lens units; and
a heat sink unit, located at one side of the substrate for dissipating heat received from the receiving units.

2. The photoelectric conversion of claim 1, wherein lens units are arranged with predetermined distances from each other around the lens module via the protruding poles.

3. The photoelectric conversion of claim 2, wherein the protruding poles provide the predetermined distances between the lens units and the tempered glass layer equally.

4. The photoelectric conversion of claim 2, wherein a height of the transparent rubber filled in the gap is similar to a height of the protruding poles.

5. The photoelectric conversion of claim 1, wherein the receiving units of the substrate are positioned respectively at focal points of the lens units or focal points adjacent to the lens units.

6. The photoelectric conversion of claim 1, wherein the heat sink unit is formed from a plurality of pole-shaped heat dissipaters.

7. The photoelectric conversion of claim 1, wherein the transparent rubber comprises properties of high coefficient of transparency and low coefficient of thermal expansion.

8. The photoelectric conversion of claim 1, wherein a thickness of the transparent rubber is approximately less than 1 mm.
